(19) United States
(12) Patent Application Publication
(10) Pub. No.: US 2023/0420057 A1
(43) Pub. Date: Dec. 28, 2023

(54) MEMORY CONTROL METHOD

(71) Applicant: DENSO CORPORATION, Kariya-city (JP)

(72) Inventor: Nao UEMATSU, Kariya-city (JP)

(21) Appl. No.: 18/463,161

(22) Filed: Sep. 7, 2023

Related U.S. Application Data
(63) Continuation of application No. PCT/JP2022/009630, filed on Mar. 7, 2022.

(30) Foreign Application Priority Data
Mar. 9, 2021 (JP) 2021-036806

(51) Int. Cl. G11C 16/16; G11C 16/10; G11C 16/34

(52) U.S. Cl. CPC G11C 16/16; G11C 16/102; G11C 16/3418

(57) ABSTRACT

A memory control method includes: writing data in at least one page that is a part of a plurality of logical sectors; erasing the data in at least one of the plurality of logical sectors; and controlling an operation for write and erasure in a memory to which an erasure voltage is applied in a physical sector including the plurality of logical sectors; and performing batch erasure for each of a plurality of logically divided physical sectors obtained by logically dividing the physical sector into at least two sectors.

### CROSS REFERENCE TO RELATED APPLICATIONS

The present application is a continuation application of International Patent Application No. PCT/JP2022/009630 filed on Mar. 7, 2022, which designated the U.S. and claims the benefit of priority from Japanese Patent Application No. 2021-036806 filed on Mar. 9, 2021. The entire disclosures of all of the above applications are incorporated herein by reference.

### TECHNICAL FIELD

The present disclosure relates to a memory control method.

### BACKGROUND

It has been known that, in a non-volatile memory that can be electrically erased all at once, that is, a flash memory, frequent erasure causes non-erasable data to be garbled due to erasure disturbance. In a comparative example, an erasure disturbance means a change in the amount of charge held in a floating gate of a memory cell in a non-selected state due to a voltage applied to the memory cell in the non-selected state during deletion of a selected cell. In the disturbance, a threshold voltage of the undesired memory cell changes. When not addressed, storage information is lost.

### SUMMARY

A memory control method includes: writing data in at least one page that is a part of a plurality of logical sectors; erasing the data in at least one of the plurality of logical sectors; and controlling an operation for write and erasure in a memory to which an erasure voltage is applied in a physical sector including the plurality of logical sectors; and performing batch erasure for each of a plurality of logically divided physical sectors obtained by logically dividing the physical sector into at least two sectors.

### BRIEF DESCRIPTION OF DRAWINGS

The above and other features and advantages of the present disclosure will become more apparent from the following detailed description taken in conjunction with the accompanying drawings.

FIG. 1 is a diagram showing a schematic configuration of a flash memory.

FIG. 2 is a schematic configuration diagram of an electric power steering device.

FIG. 3 is a diagram of a first configuration example in which a flash memory is mounted inside a controller of one microcomputer specification in the electric power steering device.

FIG. 4 is a diagram of a second configuration example in which an external flash memory is connected to the controller of one microcomputer specification in the electric power steering device.

FIG. 5 is a diagram of a third configuration example in which the flash memory is mounted inside a controller of a two-microcomputer specification in the electric power steering device.

FIG. 6 is a diagram of a fourth configuration example in which an external flash memory is connected to the controller of the two-microcomputer specification in the electric power steering device.

FIG. 7 is a diagram for illustrating the concept of the memory control method of the present embodiment.

FIG. 8 is a supplementary diagram for illustrating the meaning of symbols of n and m in a flowchart.

FIG. 9 is a flowchart of a memory control method according to a first embodiment.

FIG. 10 is a flowchart of a memory control method according to a second embodiment.

FIG. 11 is a sub-flowchart of S01B of FIG. 10.

FIG. 12 is a flowchart of batch erasure in logically divided physical sectors.

FIG. 13 is a diagram for illustrating the concept of a memory control method of a comparative example.

### DETAILED DESCRIPTION

In the comparative example, as of the flash memory, at the time of data erasure of a logical sector, the logical sector in the same physical sector receives the erasure stress, and written data is likely to be garbled. Usually, the flash memory is often designed so that data in non-erased sectors will not be garbled even when erasure stress is applied several thousand times. However, depending on internal operation parameters and design specifications of the memory, garbled data may occur due to erasure disturbance after several tens of times of erasure stress.

In response to this difficulties, the development of products by semiconductor manufacturers for improving the disturbance resistance of flash memory itself is not focused, and an approach of improving usage for preventing the occurrence of the erasure disturbance is focused from a viewpoint of a user using the flash memory.

The present disclosure provides a memory control method for avoiding an erasure disturbance of a flash memory.

The present disclosure relates to a memory control method for controlling write and erasure operations in a memory device. The memory device includes a physical sector placed on a p-well on a silicon substrate, and the physical sector includes a plurality of logical sectors connected to a wordline. In this memory device, data is written by page which is a part of logical sectors (in other words, data is written in at least one of logical sectors), and an erasure voltage is applied in physical sector units.

In the present disclosure, the physical sector is logically divided into at least two sectors, and batch erasure is performed in at least one of logically divided physical sectors.

When the erasure is arbitrarily performed within a physical sector, the erasure stress also occurs in non-erasure target logical sectors within the same physical sector each time an erasure voltage is applied. Therefore, the number of times of application of the erasure stress increases.

In contrast, in the memory control method of the present disclosure, the erasure is not performed when there is a writable logical sector, and the control is performed so that batch erasure is performed when there is no writable logical sector. Thereby, the erasure stress is generated only once for a programmed cell. Accordingly, it is possible to avoid the erasure disturbance.

An embodiment of a memory control method of the present disclosure will be described with reference to the drawings. This memory control method is a method for controlling operations related to write and erasure in a memory device. A flash memory or a microcomputer equipped with the flash memory corresponds to a “memory device”.

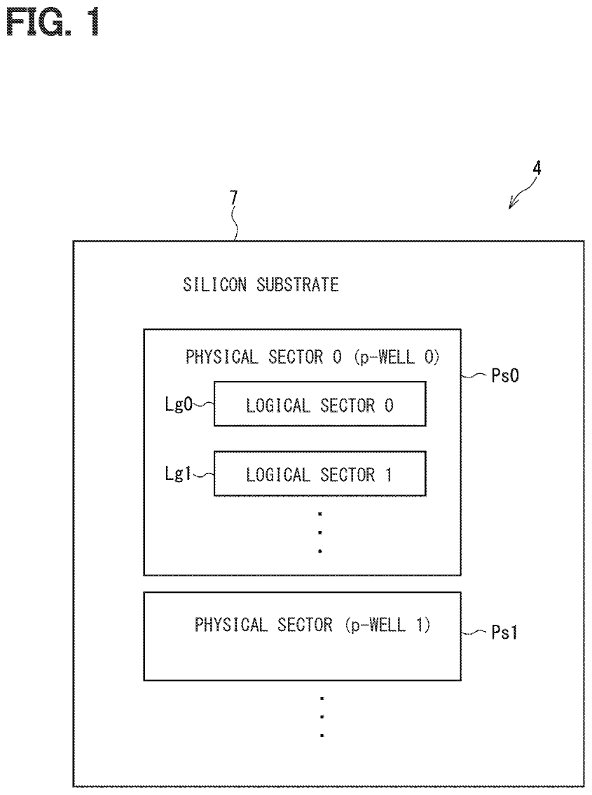

A schematic configuration of the flash memory as the “memory device” will be described with reference to FIG. 1. A flash memory 4 has physical sectors provided on a p-well on a silicon substrate 7. The physical sector includes a plurality of logical sectors connected to a word line. In this flash memory 4, data is written by pages which are part of logical sectors, data is erased in the logical sector, and a data erasure voltage is applied in at least one of physical sectors.

In FIG. 1, a code of physical sector 0 is denoted as Ps0, and a code of physical sector 1 is denoted as Ps1. The physical sector 0 is placed on a p-well 0 and the physical sector 1 is placed on a p-well 1. A code of logical sector 0 is denoted as Lg0, and a code of logical sector 1 is denoted as Lg1.

Depending on internal operation parameters and design specifications of the memory, in the flash memory, garbled data may occur due to the erasure disturbance after several tens of times of erasure stress. Therefore, the present embodiment provides a memory control method for avoiding the erasure disturbance of the flash memory.

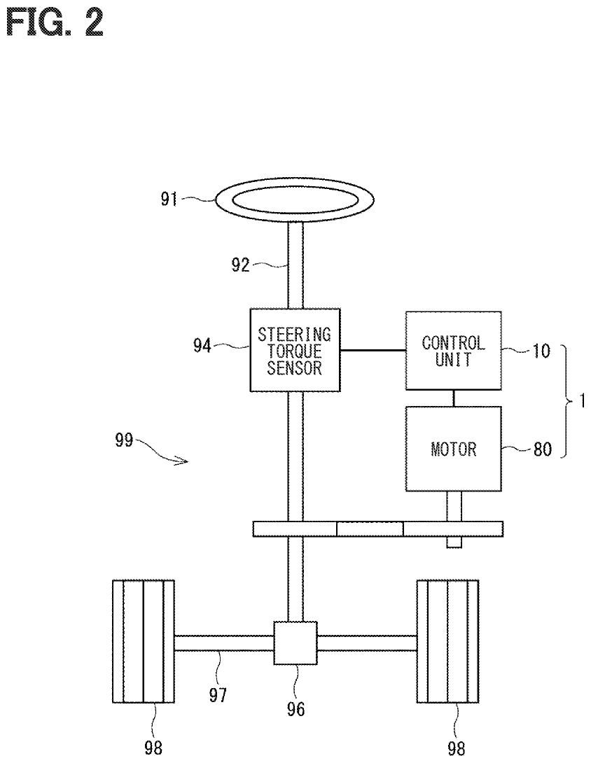

Next, with reference to FIGS. 2 to 6, a configuration example using a flash memory for a controller of a steering assist motor in an electric power steering device will be described. The flash memory is used to store control information, abnormality information, and the like related to motor energization control.

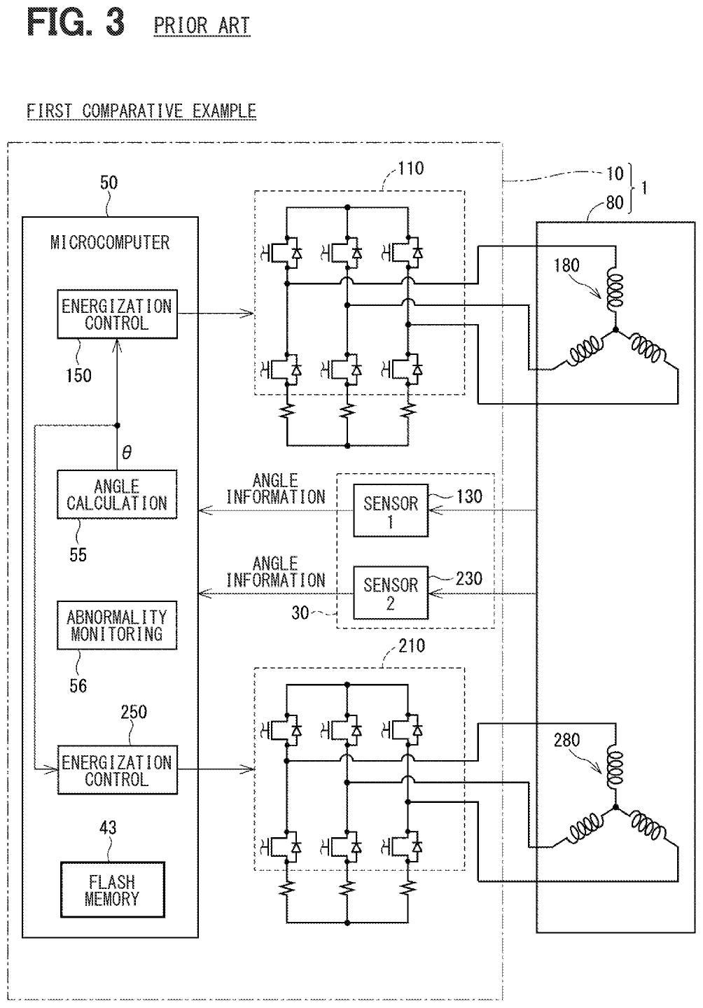

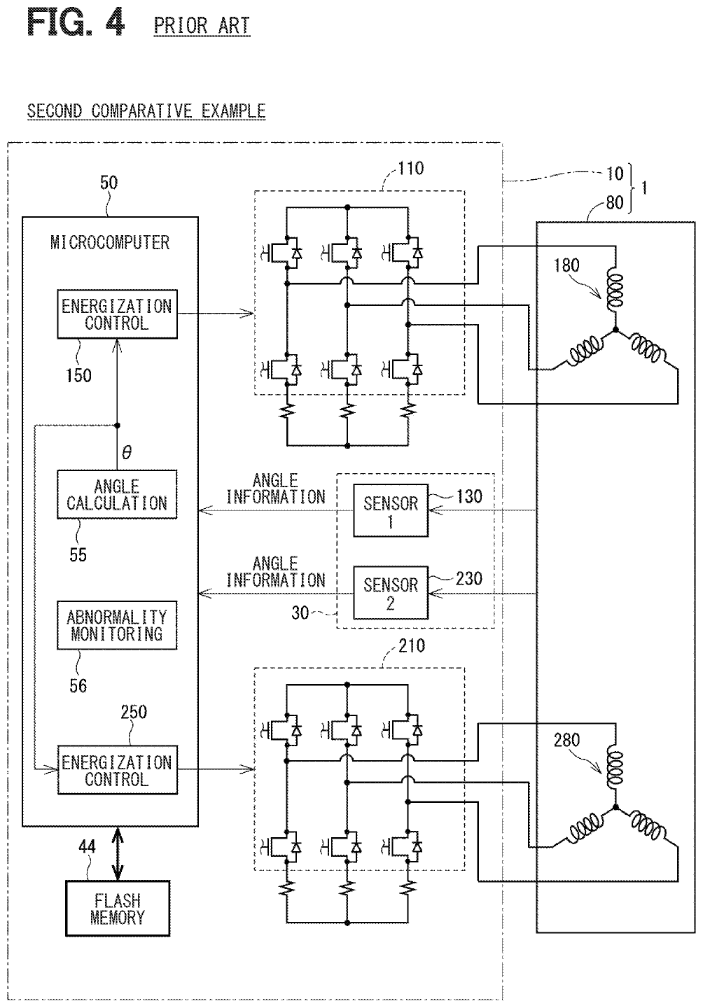

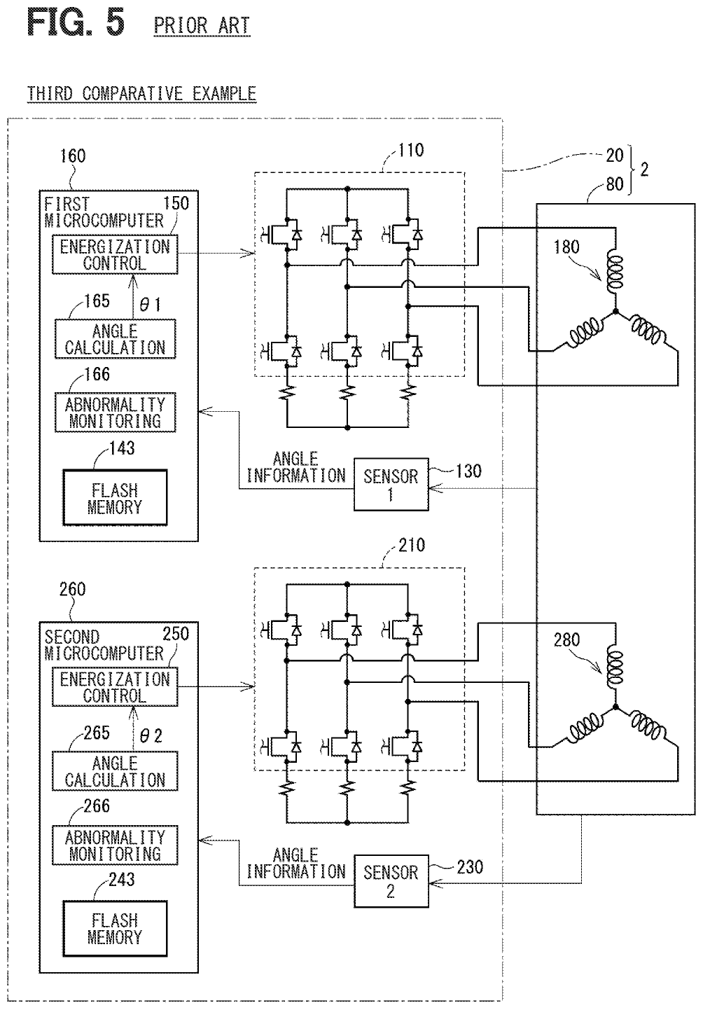

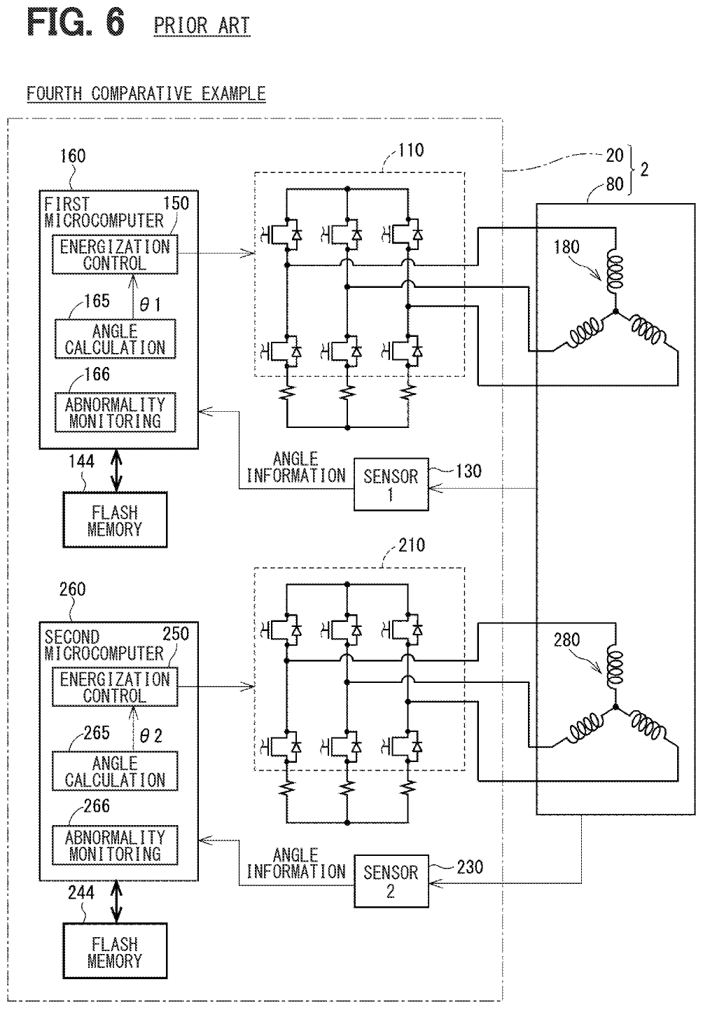

FIG. 2 shows an overall configuration of a steering system 99 including an electric power steering device 1. Although a column-assist type electric power steering device is illustrated in FIG. 2, a rack-assist type may be used. A control unit 1 is configured integrally with a motor 80, for example. In FIG. 2, reference numerals “1” and “10” corresponding to FIGS. 3 and 4 are used as reference numerals for the electric power steering device and the control unit. When the reference numerals correspond to FIGS. 5 and 6, reference numerals “2” and “20” are used.

The steering system 99 includes a steering wheel 91, a steering shaft 92, a pinion gear 96, a rack shaft 97, road wheels 98, an electric power steering device 90 and the like. The pinion gear 96 provided at an axil end of the steering shaft 92 engages with the rack shaft 97. A pair of wheels 98 are provided at both ends of the rack shaft 97. When a driver rotates the steering wheel 91, the steering shaft 92 coupled to the steering wheel 91 rotates. A rotational motion of the steering shaft 92 is converted into a linear motion of the rack shaft 97 by the pinion gear 96, and the pair of road wheels 98 is steered to an angle corresponding to a displacement amount of the rack shaft 97.

The electric power steering device 1 includes a steering torque sensor 94, a control unit 10, a motor 80, and the like. The steering torque sensor 94 detects the steering torque of the driver. The control unit 10 calculates a voltage command according to the required torque calculated from information such as the steering torque, and supplies electric power generated by the inverter to the motor 80. The steering assist torque generated by the motor 80 is transmitted to the steering shaft 92 via a reduction gear.

FIGS. 3 to 6 show configuration examples in which the flash memory is used for the microcomputer that constitutes the controller of the electric power steering device. FIGS. 3 and 4 correspond to FIG. 3 of Japanese patent literature of JP 2019-119417 (corresponding to US patent literature of US 2019-0210637 A1) which is incorporated by reference herein, and a flash memory is used for the controller of one microcomputer specification. FIGS. 5 and 6 correspond to FIG. 15 of the same literature, and the flash memory is used for the controller of a two-microcomputer specification.

First, FIGS. 3 and 4 are referred. The electric power steering device 1 includes the control unit 10 and the motor 80. The motor 80 is a double winding three-phase brushless motor having two sets of three-phase windings 180 and 280. The control unit 10 includes two systems of inverters 110 and 210 provided corresponding to the respective winding sets 180 and 280, a rotation angle sensor 30, and one microcomputer 50. The rotation angle sensor 30 includes two sensor units 130 and 230, and calculates angle information of the motor 80.

The microcomputer 50 includes two systems of energization control units 150 and 250, an angle calculation unit 55 and an abnormality monitoring unit 56. The energization control units 150 and 250 of the systems control energization from the inverters 110 and 210 to the winding sets 180 and 280 by current feedback control. The angle calculation unit 55 calculates an electrical angle θ based on angle information acquired from the rotation angle sensor 30. The electrical angle θ is used for coordinate conversion calculations of vector control and the like by the energization control units 150 and 250. The abnormality monitoring unit 56 monitors an abnormality of the rotation angle sensor 30.

In an electric power steering device that requires fail-safe performance, by using such a redundant configuration, even when an abnormality occurs in one system, the steering assist motor can continue to be driven in the different normal system. Accordingly, the amount of information processed by the microcomputer 50 increases, and the necessity for frequently storing and updating various information occurs.

In a first configuration example shown in FIG. 3, a flash memory 43 is mounted inside the microcomputer 50. In a second configuration example shown in FIG. 4, an external flash memory 44 is connected to each microcomputer 50. The flash memories 43 and 44 store information about control calculations of the microcomputer 50, abnormality information, and the like.

Next, reference is made to FIGS. 5 and 6. In FIGS. 5 and 6, substantially the same components as those in FIGS. 3 and 4 are denoted by the same reference numerals, and overlapping descriptions are omitted. An electric power steering device 2 includes a control unit 20 and the motor 80. The control unit 20 includes two systems of inverters 110 and 210 provided corresponding to the respective winding sets 180 and 280, two sensor units 130 and 230, and two microcomputers 160 and 260. That is, all the components including the microcomputer are provided redundantly for each system.

The first microcomputer 160 includes an energization control unit 150, an angle calculation unit 165, and an abnormality monitoring unit 166. The energization control unit 150 controls energization from the first inverter 110 to the first winding set 180 by current feedback control. The angle calculation unit 165 calculates an electrical angle 81 based on angle information acquired from the first sensor unit 130. The electrical angle 81 is used for coordinate conversion calculations of vector control and the like by the energization control unit 150. The abnormality monitoring unit 166 monitors an abnormality of the first sensor unit 130.

The second microcomputer 260 includes an energization control unit 250, an angle calculation unit 265, and an abnormality monitoring unit 266. The energization control unit 250 controls energization from the second inverter 210 to the second winding set 280 by the current feedback control. The angle calculation unit 265 calculates an electrical angle 82 based on angle information acquired from the second sensor unit 230. The electrical angle 82 is used for coordinate conversion calculations of a vector control and the like by the energization control unit 250. The abnormality monitoring unit 266 monitors an abnormality of the second sensor unit 230.

In a third configuration example shown in FIG. 5, a flash memory 143 is mounted inside the microcomputer 160, and a flash memory 243 is mounted inside the microcomputer 260. In a fourth configuration example shown in FIG. 6, an external flash memory 144 is connected to the microcomputer 160, and an external flash memory 244 is connected to the microcomputer 260. The flash memories 143, 144, 243, 244 store information about control calculations of the microcomputers 160, 260, abnormality information, and the like.

In common with the above first to fourth configuration examples, it is necessary for an in-vehicle system to record information such as control information during traveling and abnormality information. Writing and erasing are repeated in the flash memories 43, 44, 143, 144, 243, and 244 in the market.

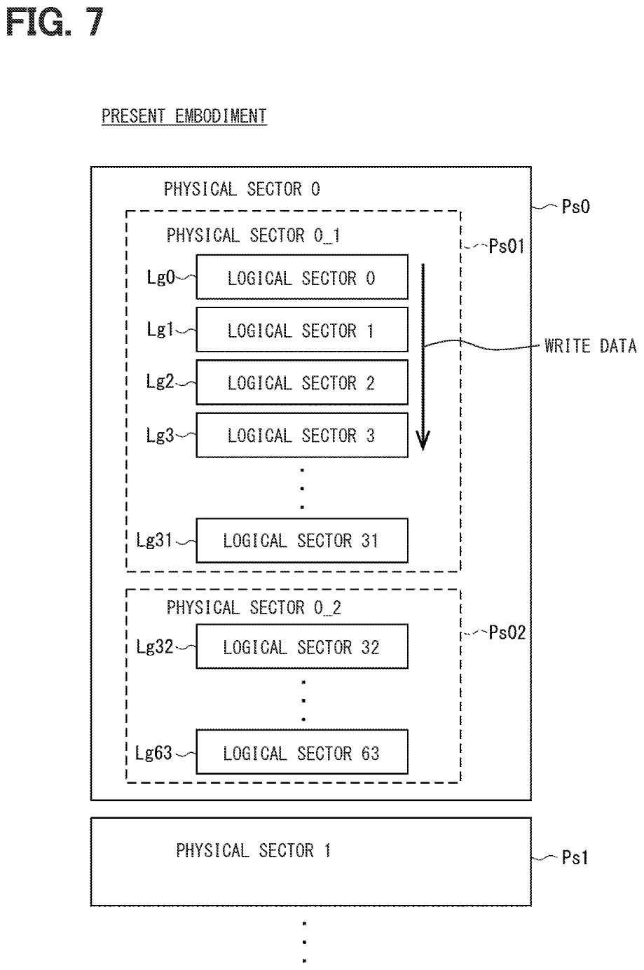

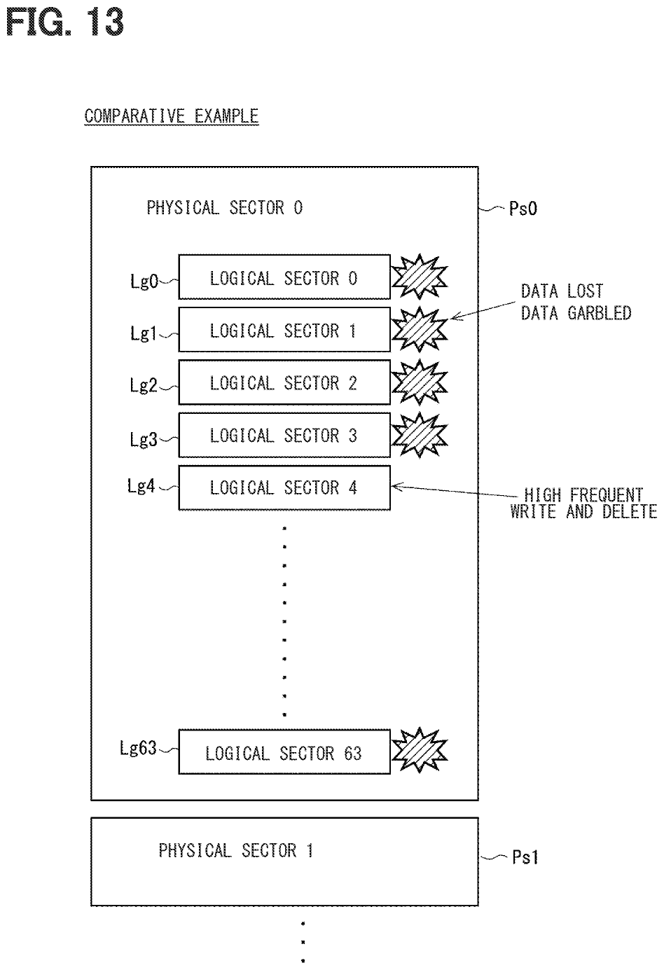

Next, with reference to FIGS. 7 and 13, the concept of the memory control method of the present embodiment will be described by comparing it with a comparative example. FIG. 13 shows a concept of a memory control method for writing and erasing data in a physical sector in an arbitrary order as the comparative example. The comparative example corresponds to a control method recognized as a general technology in the technical field of the flash memory.

In contrast to FIG. 1, physical sectors Ps0 and Ps1 and logical sectors Lg0 to Lg63 are shown in FIG. 7 and FIG. 13 for comparison with FIG. 1. Furthermore, in FIG. 7, the Ps01 and Ps02 are described as reference numerals of “logically divided physical sectors”. Since the sector names and reference numerals substantially overlap, the description of these is omitted in the specification.

In the flash memory of the comparative example shown in FIG. 13, the physical sector 0 includes sixty four sectors of logical sectors 0 to 63. When a specific logical sector (for example, logical sector 4) is frequently written and erased, data in the non-selected logical sector disappears or becomes garbled due to the erasure disturbance, as indicated by impact marks.

In contrast, in the flash memory of the present embodiment, as shown in FIG. 7, the physical sector 0 is logically divided in advance into at least two sectors, in other words, a physical sector 0_1 and a physical sector 0_2. For example, the physical sector 0_1 includes thirty two logical sectors 0 to 31, and the physical sector includes thirty two logical sectors 32 to 63.

When data is written in the physical sector 0_1, the data is written in order of logical sector 0, logical sector 1, logical sector 2, logical sector 3, . . . . Erasure is not performed until the data has been written in all logical sectors of the physical sector 0_1.

When the data in the physical sector 0_1 is erased, the data in the physical sector 0_1 is erased after the necessary data is copied to the physical sector 0_2. After that, the physical sector 0_2 is used. When the data in the physical sector 0_2 becomes full, the data in the physical sector 0_2 is similarly copied to the physical sector 0_1 and then the data in physical sector 0_2 is erased. In this way, the batch erasure is performed in at least one of logically divided physical sectors.

As in the comparative example, when the erasure is arbitrarily performed within a physical sector, the erasure stress also occurs in non-erasure target logical sectors within the same physical sector each time an erasure voltage is applied. Therefore, the number of times of application of the erasure stress increases. In contrast, in the memory control method of the present embodiment, the erasure is not performed when there is a writable logical sector, and the control is performed so that batch erasure is performed when there is no writable logical sector. Thereby, the erasure stress is generated only once for a programmed cell. Accordingly, it is possible to avoid the erasure disturbance.

Next, specific operation methods for implementing the concept of the memory control method shown in FIG. 7 will be described in a separation manner for the first and second embodiments, with reference to flowcharts and the like. In the following flowchart, a symbol S may indicate a process. In the second embodiment, processes that are substantially the same as in the first embodiment are assigned the same process numbers, and descriptions thereof are omitted. In addition, partly different processes are distinguished by adding “A” to the end of the process number in the first embodiment and adding “B” to the end of the process number in the second embodiment.

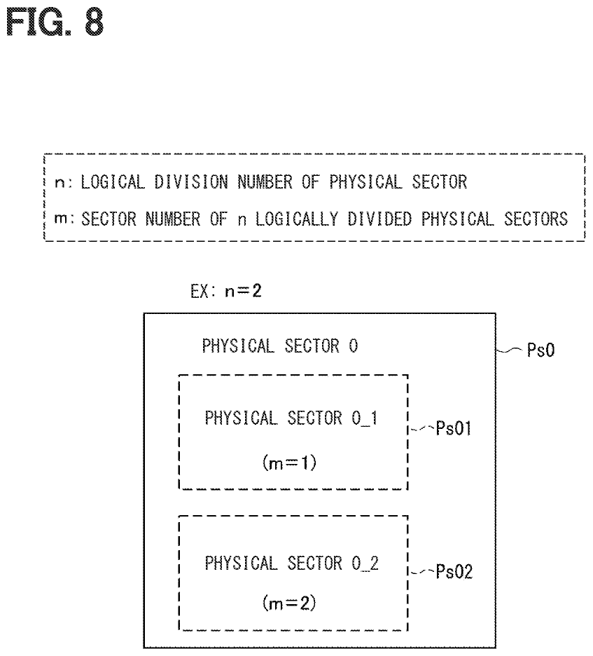

First, with reference to FIG. 8, the meanings of the natural number symbols n and m used in each flowchart will be described. Regarding FIG. 8 as well, the description of the reference numerals of Ps0, Ps01, and Ps02 is omitted in the specification. The n means the number of logical divisions of the physical sector. In the example shown in FIG. 8, the physical sector 0 is logically divided into two physical sectors 0_1 and 0_2, and the n is equal to 2 (n=2). The m means the sector number of the physical sector divided into n sectors, and is defined in a range of “1 m n”. The sector number of the physical sector 0_1 is “m=1”, and the sector number of the physical sector 0_2 is “m=2”.

In the flowchart and the following description, in parts obvious from the context, the “logically divided physical sector” is omitted and simply referred to as “physical sector” or “m-th sector”. In many parts in the flowchart, the term of “m-th sector” is used to describe a sector that is a current process target. Changing the process target sector in order from the first sector to the second sector, the third sector, and so on is expressed as “shift the process target sector downward”.

The first sector where “m=1” is also called a “head sector”, and the n-th sector where “m=n” is also called a “last sector”. In a case of “n=2”, the physical sector consists only of the head sector and the last sector. In a case of “n≥3”, a physical sector other than the head sector and the last sector is called an “intermediate sector”. For example, in the case of “n=3”, the second sector is the intermediate sector.

The main configuration for the processes in the flowchart is, for example, a memory controller in the microcomputer. In the description of the flowchart, continuous active sentences such as “The memory controller does . . . ” will be omitted. Basically, the description is made in passive sentences such as “The physical sector is done . . . ”.

### First Embodiment

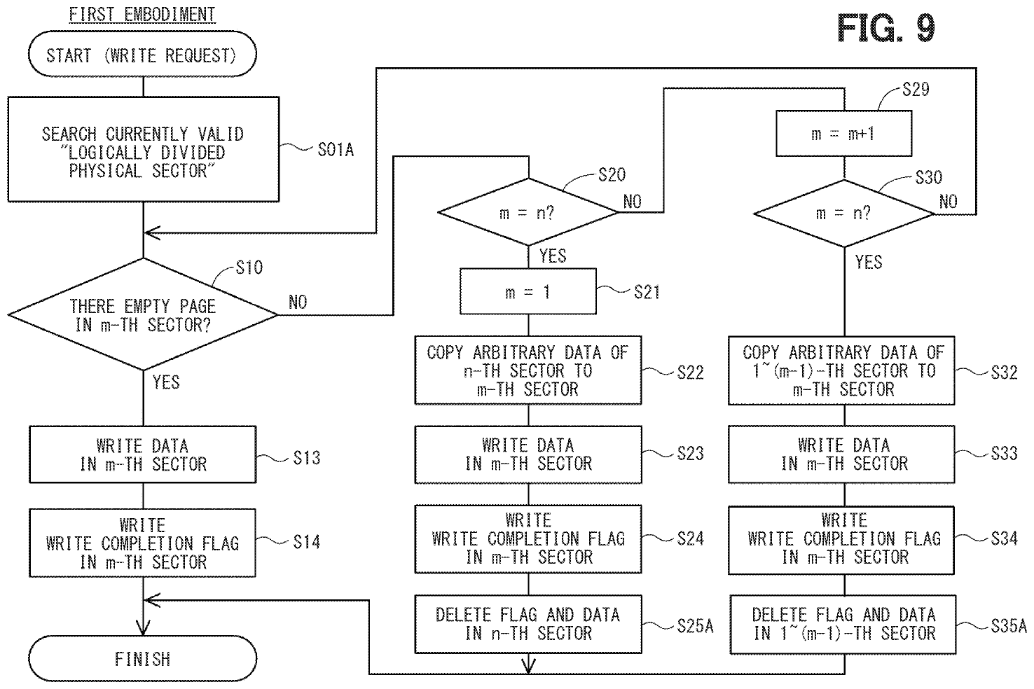

Reference is made to FIG. 9. In the memory control method of the first embodiment, when data is written, a write completion flag indicating that writing has been performed is written at the same time. The routine of FIG. 9 starts with a write request. In S01A, the currently valid “logically divided physical sector” is searched by confirming the write completion flag.

It S10, it is determined whether there is an empty page in the m-th sector. When the determination is YES in S10, data is written in the m-th sector in S13. In S14, the write completion flag is written in the m-th sector. Based on this write completion flag, an address of the next logical sector to be written is determined.

When the determination is NO in S10, the process proceeds to S20. In S20, it is determined whether the m is equal to the n (m=n), that is, whether the sector having no empty page is the last sector. When there is no empty page in the last sector, the determination is YES.

When the determination is YES in S20, “m=1” is set in S21, and the processes of S22 to S24 are executed with the head sector as the process target sector. In S22, arbitrary data in the n-th sector (that is, the last sector) is copied to the m-th sector. In S23, data is written in the m-th sector. In S24, the write completion flag is written in the m-th sector. In S25A, the flag and data of the n-th sector (that is the last sector) are erased.

When the determination is NO in S20, after the shift of “m=m+1” in S29, it is determined whether the m is equal to the n (m=n) again in S30. In the case of “n=2”, there is only “m=2” after S29, and the determination is always YES in S30. In the case of “n=3”, when the m is equal to 3 (m=3) after S29, the determination is YES in S30. When the m is equal to 2 (m=2) after S29, the determination is NO in S30.

When the determination is YES in S30, the processes of S32 to S34 are executed with the m-th sector at this time as the process target sector. In S32, arbitrary data of the 1st to (m−1)-th sectors are copied to the m-th sector. In S33, data is written in the m-th sector. In S34, the write completion flag is written in the m-th sector. In S35A, the flags and data of the 1st to (m−1)-th sectors are erased.

In a case where the n is equal to less than 3 (n≥3), the determination is NO in S30, the process returns to S10 and the process is repeated. In the case of “n=3”, the determination is always YES in S30 of the second loop. That is, the loop is repeated up to (n−1) times according to the number n of logically divided physical sectors.

As described above, in the memory control method of the first embodiment, when arbitrary data is written in a logical sector, the write completion flag indicating that writing has been performed is further written. Then, based on this write completion flag, an address of the next write target logical sector is determined. Using the write completion flag facilitates determination by the memory controller.

Writing in the logical sector is performed in a predetermined order. Thereby, it is possible to reliably determine the presence or absence of the write according to a predetermined procedure. In addition, it is possible to perform the control so that the erasure voltage stress to the written cells is only once.

Arbitrary data written in the logically divided physical sector is copied to a different unwritten logically divided physical sector before the batch erasure of the data in the logically divided physical sector. Thereby, it is possible to prevent the loss of potentially usable data.

### Second Embodiment

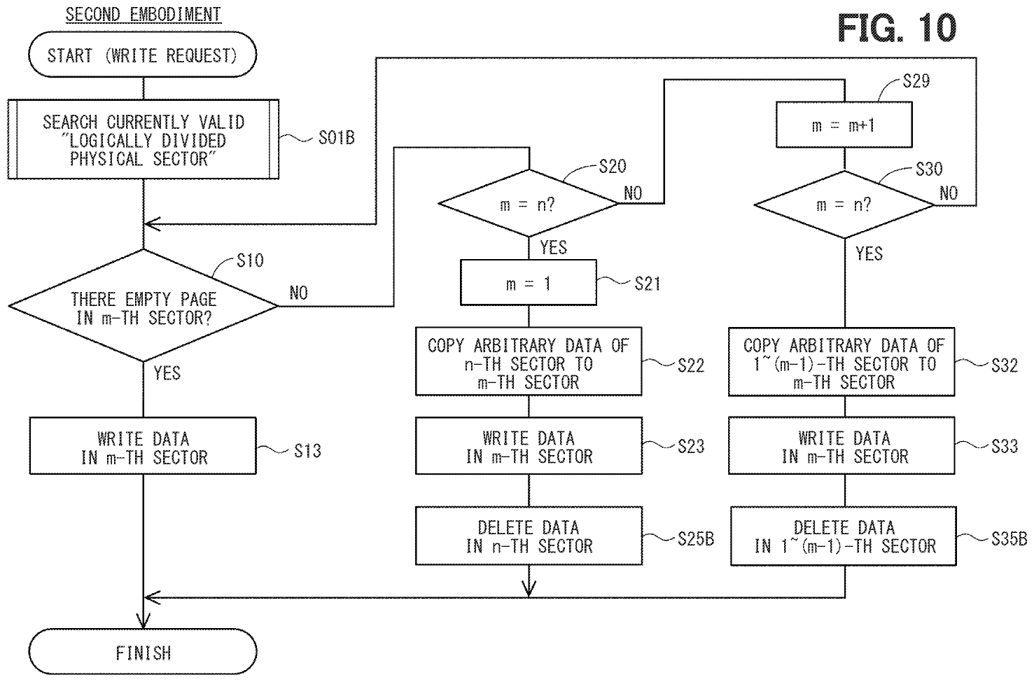

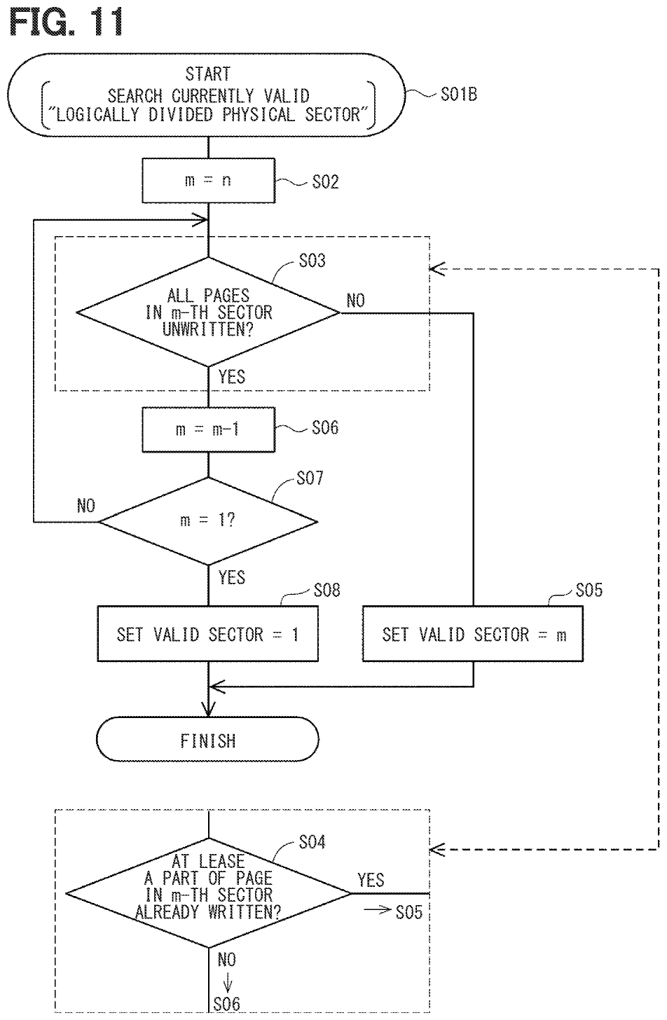

Reference is made to FIGS. 10 and 11. In a memory control method of a second embodiment, it is determined whether data has been written in the physical sector. The routine of FIG. 10 starts with a write request. In S01B, a currently valid “logically divided physical sector” is searched. The search method is different from the portion of “by confirming the write completion flag” in the first embodiment.

A sub-flowchart of FIG. 11 shows the search method for S01B. In S02, “m=n” is set, and the search starts from the last sector. In S03, it is determined whether all pages of the m-th sector are unwritten. When all pages of the m-th sector are unwritten, the determination is YES in S03, and the process proceeds to S06. When at least some pages of the m-th sector have been written, the determination is NO in S03, and the process proceeds to S05.

Supplementally, the process in S03 can be changed to an inverse determination process in S04 of “Has at least some pages in the m-th sector been written?”. In a case where the process in S04 is used, when the determination is YES, the process proceeds to S05. When the determination is NO, the process proceeds to S06.

The currently valid “logically divided physical sector” of S01B is abbreviated as “valid sector”. In S05, “valid sector=m” is set. That is, the m-th sector is selected as a writable valid sector. In S06, “m=m−1” is set, and the search target is changed in order from the last sector to the head sector.

In S07, it is determined whether “m=1”, that is, whether the search has reached the head sector. When the determination is NO in S07, the process returns to the process before S03 or S04, and determination of the write state is repeated. When the determination is YES in S07, “valid sector=1” is set in S08. That is, the m-th sector is selected as the head sector. Based on the selected valid sector, an address of the next written target logical sector is determined.

Returning to FIG. 10, the outline of processes S10 to S35B is the same as in FIG. 9 of the first embodiment. As compared with FIGS. 9, S14, S24, and S34 regarding writing of the write completion flag are absent. Further, the “flag & data erasure” in S25A and S35A of FIG. 9 is changed to “data erasure” in S25B and S35B of FIG. 10. Based on the valid sector set in S01B, the process in S10 and the subsequent processes are executed in the same manner as in FIG. 9, except for the process related to the write completion flag.

As described above, in the memory control method of the second embodiment, the address of the next written target logical sector is determined based on whether data has been written in the logically divided physical sector. Thereby, it is possible to perform the similar control to the first embodiment without using the write completion flag.

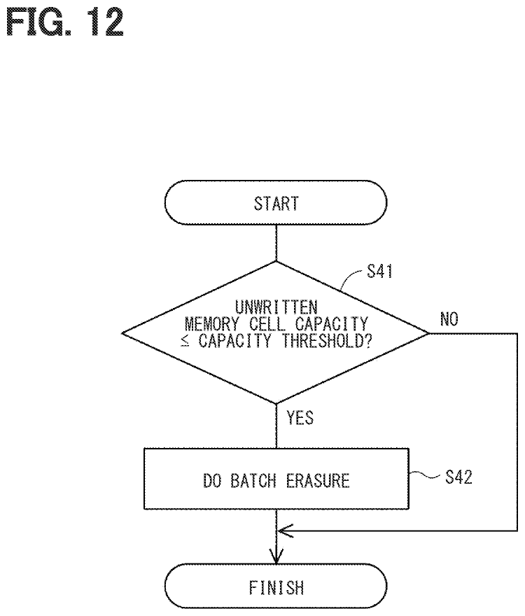

Batch erasure in at least one of logically divided physical sectors will be described with reference to a flowchart of FIG. 12. In S41, it is determined whether the capacity of unwritten memory cells in the logically divided physical sector is equal to or less than a predetermined capacity threshold. When the determination is YES in S41, the batch erasure is performed in at least one of logically divided physical sectors in S42.

### Other Embodiments

(1) A specific operation method for implementing the memory control method of the present disclosure is not limited to the methods shown in the flowcharts of FIGS. 9 to 11. For example, the order of search for the currently valid “logically divided physical sectors” may be changed. The write in the logical sector is not necessarily performed in the predetermined order.

(2) The memory control method of the present disclosure may be applied not only to the controller of the electric power steering device, but also to a controller of any device using the flash memory. The present disclosure is particularly effective in systems in which data is frequently written and erased.

The present disclosure is not limited to the above embodiments but various modifications may be made further within the scope of the present disclosure without departing from the spirit of the disclosure.

The present disclosure has been made in accordance with the embodiments. However, the present disclosure is not limited to such embodiments and configurations. The present disclosure also encompasses various modifications and variations within the scope of equivalents. Furthermore, various combination and formation, and other combination and formation including one, more than one or less than one element may be made in the present disclosure.

Here, the process of the flowchart or the flowchart described in this application includes a plurality of sections (or steps), and each section is expressed as, for example, S41. Further, each section may be divided into several subsections, while several sections may be combined into one section. Furthermore, each section thus configured may be referred to as a device, module, or means.

1. A memory control method, wherein
a physical sector is placed on a p-well on a silicon substrate,
the physical sector includes a plurality of logical sectors connected to a wordline,
the method includes:
writing data in at least one page that is a part of the plurality of logical sectors;
erasing the data in at least one of the plurality of logical sectors; and
controlling an operation for write and erasure in a memory to which an erasure voltage is applied in the physical sector; and
performing batch erasure for each of a plurality of logically divided physical sectors obtained by logically dividing the physical sector into at least two sectors.

2. The memory control method according to claim 1, wherein
the write in the logical sector is performed in a predetermined order.

3. The memory control method according to claim 1, further comprising:
further writing a write completion flag indicating that the write has been performed when arbitrary data is written in the logical sector; and
determining an address of a logical sector that is a next write target among the plurality of logical sectors based on the write completion flag.

4. The memory control method according to claim 1, further comprising
determining an address of a logical sector that is a next write target among the plurality of logical sectors based on a determination of whether the data has been written in the plurality of logically divided physical sectors.

5. The memory control method according to claim 1, further comprising
determining a capacity of an unwritten memory cell of the plurality of logically divided physical sectors; and
performing the batch erasure of the at least one of the plurality of logically divided physical sectors when the capacity of the unwritten memory cell is equal to or less than a predetermined capacity threshold.

6. The memory control method according to claim 1, further comprising
copying arbitrary data written in the plurality of logically divided physical sectors to an unwritten different logically divided physical sector before the batch erasure of the data in the plurality of logically divided physical sectors.
